(19) United States
(12) Patent Application Publication
(10) Pub. No.: US 2024/0006251 A1
(43) Pub. Date: Jan. 4, 2024

(54) SEMICONDUCTOR WAFER WITH A HIGH DENSITY OF PRIME INTEGRATED CIRCUIT DIES CONTAINED THEREIN

(71) Applicant: pSemi Corporation, San Diego, CA (US)

(72) Inventor: Tran KONONOVA, SAN DIEGO, CA (US)

(21) Appl. No.: 17/810,566

(22) Filed: Jul. 1, 2022

(51) Int. Cl. H01L 21/66; H01L 23/544; H01L 23/00; H01L 23/528; H01L 21/768

(52) U.S. Cl. CPC H01L 22/32; H01L 23/544; H01L 24/04; H01L 23/5283; H01L 21/76892; H01L 2223/54426; H01L 2224/0401

(57) ABSTRACT

Semiconductor wafers containing prime dies, knockout dies, and hybrid dies are presented. Corresponding singulated semiconductor chips containing the prime dies are also presented. The knockout dies contain a multiplicity of electrical test structures and optionally optical alignment dies. The hybrid dies may contain various combinations of electrical test structures, optical alignment structures, and serpentine shaped conductor. The serpentine shaped conductor in the hybrid die is designed to have a high confidence of overlaying at least three under bump metallization pads in the hybrid die that are oriented in the same way as at least three under bump metallization pads of a prime die. The serpentine shaped conductor is part of a two-wire Kelvin resistance scheme. A method of converting a prime die into a hybrid die includes the steps of selecting, providing, irradiating, stripping, adding, and forming.

### FIELD

The present disclosure relates to semiconductor integrated circuits, and more particularly to placement designs of quality control structures for use in maximizing the number of integrated circuits (IC) on a given wafer and improving the quality of the IC.

### BACKGROUND

In accordance to Moore's Law, the semiconductor industry has continued to double device densities nearly every 18 months. As semiconductor process technology relentlessly advances into deeper submicron feature sizes, the cost of mask tooling has grown inexorably, up to 1, 1.5, and 3 million dollars for 90 nm, 65 nm, and 32 nm process technology, respectively. This doubling has been driven by innovative processes and designs which result in increasingly complex and compact semiconductor chips that now routinely contain millions of transistors, and other structures such as capacitors, resistors, diodes, etc. These structures must subsequently be interconnected together to form the resultant circuits. This high degree of complexity makes it necessary to measure not only the output signals of the entire resultant circuit but makes it necessary to also measure the signals of individual internal functional groups of a circuit. To assure satisfactory performance of these resultant circuits, they are routinely tested electrically and optically before being separated into individual semiconductor chips. Electrical testing involves monitoring for electrical shorts, opens, resistance, etc. Optical testing is used to assure proper structure alignment, critical dimension, etc.

Optical and electronic test structures are conventionally formed in regions referred to as “knockout” areas. Accordingly, knockout areas are areas that are used to concentrate and to sequester optical and electrical test structures away from the product IC. As integrated circuits on chips become more complicated, the number of necessary test structures has significantly increased, as has the space required to accommodate such structures. The increasing wafer space required for incorporating test structures imposes a limitation on the number of chips which may be formed from the wafer.

By narrowing the width of the scribe streets more integrated circuits can be placed onto a given wafer. However, this strategy of increasing chip density on wafers has concomitantly resulted in dramatically decreasing the available areas for placement of test structures that are often placed in the scribe streets. This gives rise to the challenge of where to place these test structures when the scribe streets are too narrow to accommodate them. Even if test structures can be mounted within these narrower scribe streets subsequent singulation may give rise to lowered throughput of functional chips due to interfering particles generated during the singulation process along these narrower scribe streets.

The disadvantage of the known methods, according to the state of the art, is that the areas needed for these test structures occupy a substantial part of the total area of the wafer. In the case of small, but highly integrated circuits, these knockout areas may displace multiple product ICs and may interfere with certain types of test structures. This type of situation gives rise to a substantial increase in the total cost of the product IC which has a negative effect on profitability.

Therefore there are simultaneous needs of how to efficiently pack wafers with as many circuit chips as possible to increase profitability while assuring that the wafers are designed to have adequate room for placement of electrical test structures and optical alignment structures.

### SUMMARY

According to a first embodiment, a semiconductor wafer is provided, comprising: i) a plurality of prime dies, each prime die comprising: a prime integrated circuit, and a plurality of under bump metallization pads on the prime integrated circuit; and ii) at least one hybrid die comprising: a) a measurement zone comprising: a serpentine shaped conductor; and at least three under bump metallization pads coupled to the serpentine conductor wherein the at least three under bump metallization pads of the measurement zone of the hybrid die are aligned to match positions of at least three under bump metallization pads of the prime dies; and b) a reclaimed zone comprising a first plurality of electrical test structures.

According to a second embodiment, a semiconductor wafer is provided, comprising: i) a plurality of prime dies, each prime die comprising: a prime integrated circuit, and a plurality of under bump metallization pads on the prime integrated circuit; and ii) at least one hybrid die comprising: a) a measurement zone comprising: a serpentine shaped conductor; and under bump metallization pads coupled to the serpentine conductor; and b) a reclaimed zone comprising: a first plurality of electrical test structures; and at least one optical alignment structure; and c) a plurality of knockout dies comprising a second plurality of electrical test structures, and at least one optical alignment structure.

According to a third embodiment, a method of converting a prime die into a hybrid die is provided, the method comprising: selecting a first zone of the prime die on a semiconductor wafer that contains at least three under bump metallization pads; providing a lithographic region configured to overshadow the first zone; irradiating the prime die, using the lithographic region to overshadow the first zone, to expose a second zone of the prime die wherein the second zone is adjacent to the first zone; stripping the second zone to remove circuitry structures to form a reclaimed zone of the hybrid die; adding electrical structures and at least one optical alignment structure onto the reclaimed zone; and forming a serpentine shaped conductor on the at least three under bump metallization pads of the first zone to form a measurement zone of the hybrid die.

### BRIEF DESCRIPTION OF THE DRAWINGS

The present disclosure is best understood from the following detailed description when with the accompanying figures. Various features may not be drawn to scale and used for illustration purposes only. In fact, the dimensions of the various features may be arbitrarily increased or reduced for clarity of discussion.

FIG. 1 depicts a stylized top view of one embodiment of a semiconductor wafer showing a plurality of reticle imprints on the semiconductor substrate and showing an expanded top view of one of the reticle imprints, including prime integrated circuit dies, knockout dies, and an alignment die.

FIG. 2 depicts some representative known examples of optical alignment structures. Panel (a) depicts a stylized top view of a cross shaped optical alignment structure. Panel (b) depicts a stylized top view of nested ellipses shaped optical alignment structure. Panel (c) depicts a stylized top view of another nested ellipses shaped optical alignment structure. Panel (d) depicts a stylized top view of another nested crosses shaped optical alignment structure. Panel (e) depicts a stylized top view of a nested rectangular shaped optical alignment structure.

FIG. 3 depicts some representative known examples of electrical test structures. Panel (a) depicts a stylized top view of an electrical test structure comprising a resistor circuit coupled to under bump metallization pads. Panel (b) depicts a stylized top view of another electrical test structure comprising a capacitor circuit coupled to under bump metallization pads. Panel (c) depicts a stylized top view of another electrical test structure comprising a transistor circuit coupled to under bump metallization pads. Panel (d) depicts a stylized top view of another electrical test structure comprising a NOR gate circuit coupled to an under bump metallization pad. Panel (e) depicts a stylized top view of another electrical test structure comprising a test inspection circuit coupled to under bump metallization pads. Panel (f) depicts a stylized top view of another electrical text structure comprising a multiplexer coupled to a test inspection circuit coupled to under bump metallization pads.

FIG. 4 depicts a stylized top view of a known alignment die comprising a plurality of under bump metallization pads coupled to two linear electrical lines that are perpendicular to each other.

FIG. 5 depicts a knockout die composed of an optical alignment structure and a plurality of electrical test structures.

FIG. 6 depicts an expanded top view of a reticle imprint on a semiconductor wafer showing a hybrid die and knockout dies positioned at center and four corner areas of the reticle imprint in accordance with an embodiment of the present disclosure.

FIG. 7 depicts a stylized top view of a hybrid die composed of a plurality of electrical test structures and a serpentine-shaped electrode or conductor overlaying at least three under bump metallization pads in accordance with an embodiment of the present disclosure.

FIG. 8 depicts a stylized magnified close up top view of a serpentine shaped conductor.

FIG. 9 depicts a stylized cross-sectional view of a serpentine shaped conductor with an overlying bump.

FIG. 10 depicts a stylized top view of a portion of a reticle imprint that corresponds to a prime die showing a plurality of under bump metallization pads distributed on a prime integrated circuit die in accordance with an embodiment of the present disclosure, and showing a region overlapping and shadowing over a part of the reticle imprint of the prime die resulting in some under bump metallization pads being shadowed by the overlapping region.

FIG. 11 depicts a hybrid die formed from the arbitrarily selected reticle imprint of the prime integrated circuit die of FIG. 10 in accordance with an embodiment of the disclosure. FIGS. 10-11 show a one-to-one alignment between the hybrid and prime IC dies.

The same reference numerals refer to the same parts throughout the various figures.

### DETAILED DESCRIPTION

Throughout this description, the preferred embodiment and examples shown should be considered as exemplars, rather than as limitations on the teachings of the present disclosure.

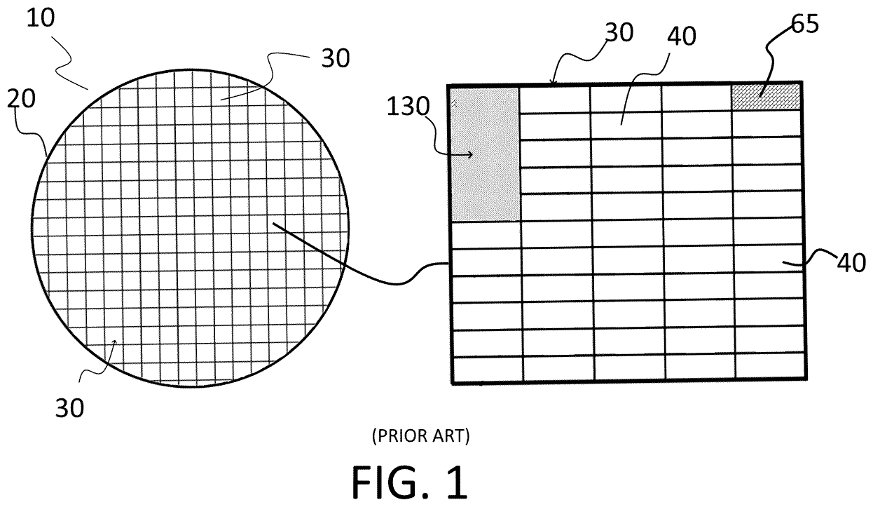

FIG. 1 depicts a stylistic top view of an embodiment of a semiconductor wafer (10) that includes a plurality of reticle imprints (30) formed on a semiconductor substrate (20). An expanded top view of an individual reticle imprint (30) of the semiconductor wafer is shown to include a plurality of prime dies (40) distributed throughout the reticle imprint. Also shown is a knockout die (130) positioned in a corner of the reticle imprint, and an alignment die (65) located in another corner of the reticle imprint. The knockout die size can be as large as ten to twenty times larger than the size of an individual prime die. The alignment die (65) is shown to be the same size as that of individual prime dies by way of example and not of limitation.

The prime dies (40) are those IC dies that have a commercial demand or at least those that are intended to be sold or provided to customers. Accordingly, the prime dies may have any number of different circuitry configurations and therefore there are no limits to the sizes and types of the prime dies. The prime dies may be individually singulated from the semiconductor wafer into semiconductor chips. These semiconductor chips may have eventual use in various electronic products and alike. Alternatively, the semiconductor wafers or subgrouping of the prime dies may be grouped together or stacked in a ‘waffle’ pack for shipment to a customer.

The semiconductor wafer (10) includes a silicon semiconductor substrate (20) or other proper substrate having material layers formed thereon. Other proper substrate materials include suitable elementary semiconductors, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. A most preferred variation of the semiconductor substrate is that it is made of single crystalline silicon.

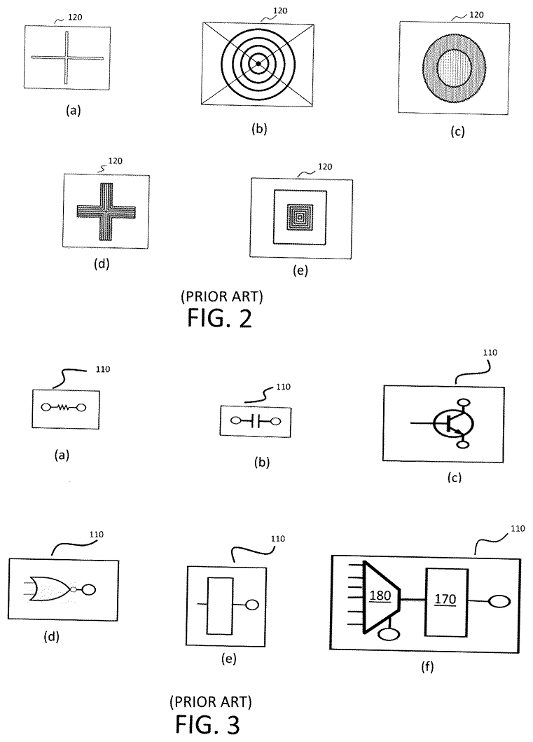

Panels (a)-(e) of FIG. 2 provide a few examples of the different types and sizes of optical alignment structures (120) used in semiconductor fabrication facilities and similar industries. Panel (a) depicts a stylized top view of a cross shaped optical alignment structure. Panel (b) depicts a stylized top view of a crossed out nested ellipses shaped optical alignment structure. Panel (c) depicts a stylized top view of a nested ellipses shaped optical alignment structure, sometimes called bullseyes optical alignment structures. Panel (d) depicts a stylized top view of a nested cross shaped optical alignment structure. Panel (e) depicts a stylized top view of a nested rectangular optical alignment structure, sometimes called pyramidal optical alignment structure. There are no limitations imposed on the relative size differences of the various optical alignment structures. That is, wafer fabrication processing often requires a series of different magnified procedures ranging from relatively low to extremely high-resolution work. Highly magnified processing may require relatively tiny optical alignment structures whereas lower magnified processing may require much larger optical alignment structures. For example, tape and reel procedures may require relatively large optical alignment structures for use in low resolution procedures.

Panels (a)-(f) of FIG. 3 depict some representative examples of electrical test structures (110). Dies of electrical test structures can occupy between 2-20 prime die sites. Panel (a) depicts a stylized top view of an electrical test structure comprising a resistor circuit coupled to under bump metallization (UBM) pads. Panel (b) depicts a stylized top view of another electrical test structure comprising a capacitor circuit coupled to UBM pads. Panel (c) depicts a stylized top view of another electrical test structure comprising a transistor circuit coupled to UBM pads. Panel (d) depicts a stylized top view of another electrical test structure comprising a NOR gate circuit coupled to an UBM pad. Panel (e) depicts a stylized top view of another electrical test structure comprising a test inspection circuit coupled to UBM pads. Panel (f) depicts a stylized top view of another electrical test structure comprising a multiplexer (180) coupled to a test inspection circuit (170) and to UBM pads.

The electrical test structures may be as simple as a resistor or a capacitor. Electrical test structures can become more complex ranging from transistors, logic gates such as a NOR gate. Electrical test structures can include individual test inspection circuits with a multiport multiplexer coupled to multiple parts of either a prime die or a plurality of prime dies. The sizes of the electrical test structure. Any number of different configurations of electrical test structures, commercially used in fabrication facilities and similar industries, are envisioned to be suitably applicable herein as electrical test structures. There are no limitations imposed on the relative size differences of the various electrical test structures.

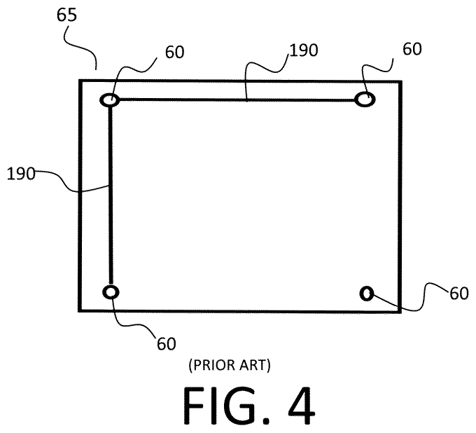

FIG. 4 depicts a stylized top view of an embodiment of a known alignment die (65) comprising two linear electrical lines (190) coupled to three of four UBM pads (60). The alignment die makes up 0.2% to 1.0% of the wafer depending on the die size. The four UBM pads (60) are positioned in the four corners of the alignment die (65). Three of the four UBM pads are coupled to the two linear electrical lines (190). The optional fourth UBM pad (60) is not connected to the electrical lines. The two linear electrical lines are perpendicular to each other and are jointly coupled to one UBM pad. The alignment die (65) may be used in a fabrication and post fabrication processes. Some of the uses of the alignment die in post fabrication processes may include bump placement, sort testing, singulation, automatic optical inspection, and tape and reel operations. The two perpendicular linear electrical lines coupled to three UBM pads function as part of a two-wire measurement scheme for monitoring layer resistances of the semiconductor wafer (10). This two-wire measurement scheme for monitoring layer resistances is sometimes referred to as a two-wire Kelvin resistance measurement scheme.

The alignment die (65) is used for multiple purposes such as being used in a resistance measurement scheme and as being used in optically align the wafer, then no other structures can be used in any remaining portion of the alignment die. Metal dummy fill is often added so that the empty area does not have very different etch rates from the rest of the reticle. The metal dummy fill is not electrically connected to other parts and only serves as a filler. This leaves the alignment die void of anything electrical except the two linear electrical lines and the four UBM pads. As a result, the alignment die size is the same as the prime die but there are only two metal lines occupying the entire width and length of the die apart from the metal dummy fill. The two linear electrical lines of the alignment die that are perpendicular to each other result in occupying an entire area equivalent to a prime die (40). Accordingly, there is a long felt need to somehow transform this known alignment die into a more compressed two-wire Kelvin resistance measurement scheme to reclaim the void spaces of the alignment die for use in placing other functional devices such as electrical test structures (110) and optical alignment structures (120). Optionally, the reclaimed void spaces of the alignment dies can be used to include smaller test dies that effectively allow production of limited quantities of projected upcoming dies for subsequent testing purposes.

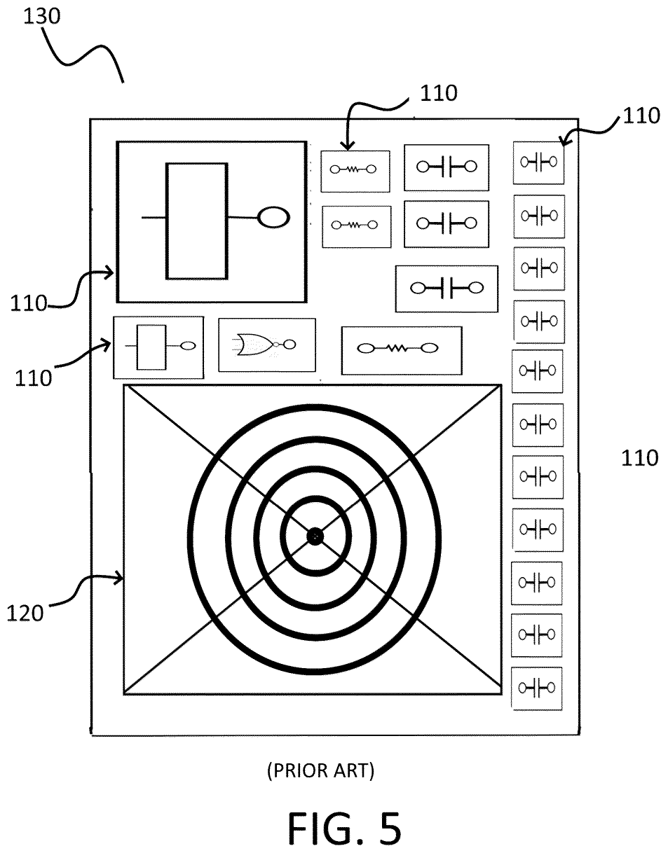

FIG. 5 shows a knockout die (130) composed of a plurality of electrical test structures 9110) and an optical alignment structure (120).

Optical alignment structures (120) incorporated in knockout dies (130) can be any number of different types and sizes of optical alignment structures used in fabrication facilities and similar industries (shown in FIGS. 2 and 5). Some representative examples of optical alignment structures used include multiple optical alignment structures that can also be incorporated into a single knockout die that can provide multi-resolution functions. For example, relatively large optical alignment structures can be incorporated into the knockout dies for use in relatively low-resolution fabrication and post fabrication process. In contrast, relatively small optical alignment structures can be incorporated into the knockout dies for use in relatively high-resolution fabrication and post fabrication processes.

Electrical test structures (110) incorporated in knockout dies (130) can be any number of different types and sizes of configurations of electrical test structures used in fabrication facilities and similar industries (as shown in FIGS. 3 and 5). Some electrical test structures can include relatively simple electrical components such as resistor or capacitor components. Transistors are also known to function as components of the electrical test structures. Logic gates, such as a NOR gate, can also be incorporated as electrical test structures. Specific designed test inspection circuits and multiplexers (see panel (f) of FIG. 3) can also be included as electrical test structures in the knockout die. The relative sizes of each individual electrical test structure need not be the same size. Accordingly, there is a wide variety of different types of electrical test structures known in the art of semiconductor fabrication that are available for placement into the knockout die.

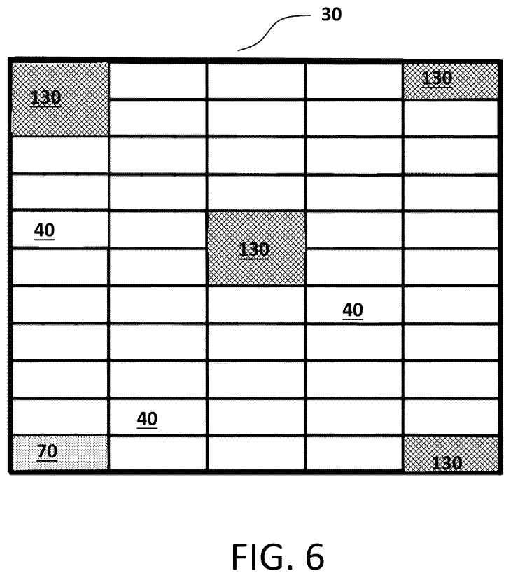

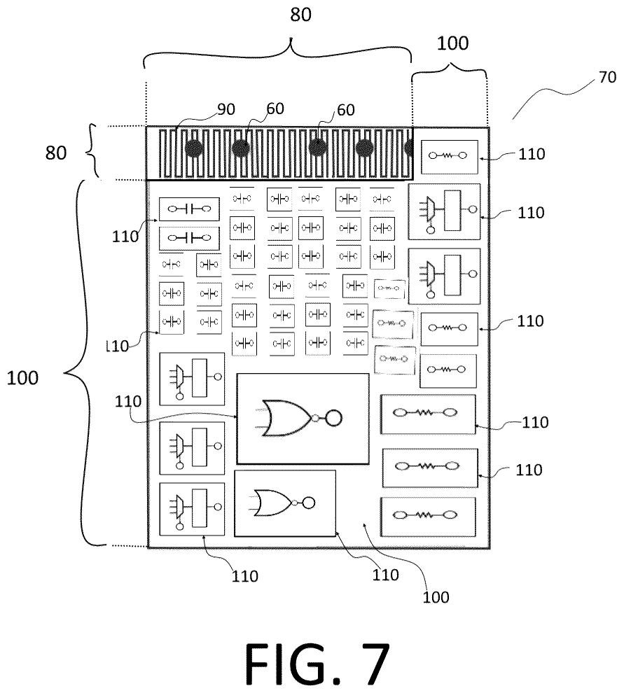

FIG. 6 depicts an expanded top view of a reticle imprint (30) of the semiconductor wafer in accordance with an embodiment of the present disclosure, incorporating a plurality of prime dies (40), four knockout dies (130) and a hybrid die (70) (see also FIG. 7 and description below). The four knockout dies and the hybrid die are shown configured in the four corners and center of the updated reticle imprint which can then be used to alignment the updated reticle during fabrication.

FIG. 7 depicts one embodiment of a stylized top view of a hybrid die (70) composed of a plurality of electrical test structures (110) and a serpentine electrode or conductor (90) overlaying at least three UBM pads (60). The presently disclosed method of making the hybrid die results in the at least three UBM pads of the hybrid die being identically aligned to corresponding UBM pads of the prime die. This motivation of having the at least three UBM pads of the hybrid die aligned to the same locations as those of the prime die provides a number of advantages, such as realizing a quick assignment of test probe pins during testing. This innovation also provides the advantage of minimizing damage to test probe pins due to misalignment during probing operations.

The electrical test structures (110) are positioned in a reclaimed zone (100) of the hybrid die (70) and the serpentine electrode (90) is positioned in a measurement zone (80) of the hybrid die. The electrical test structures as such have been described above and depicted in FIGS. 3 and 5.

The reclaimed zone (100) of the hybrid die (70) is designed to be considerably larger than the measurement zone (80) to maximize placement of electrical structures in the measurement zone of the hybrid die. Up to 92% wasted space of one alignment die per reticle can be, for example, reclaimed by folding the two linear electrical lines (See FIG. 4 item (190)) into a compressed measurement zone. The size of the reclaimed zone of the hybrid die may range from ten to over one hundred times relative the size of the measurement zone.

The serpentine shaped conductor (90) is confined within the measurement zone (80) of the hybrid die (70). In the embodiment shown in FIG. 7, the serpentine shaped conductor (90) is shown to be overlain by four and a half UBM pads (60). The minimum area of the serpentine shaped conductor is designed to preferably achieve an over 95% confidence of overlapping at least three UBM pads that correspond to at least three UBM pads of a prime die. The shape of the serpentine shaped conductor can be any known electrical conduit shape known in the semiconductor design and fabrication arts. However, using a long straight electrode having an area sufficient to overlap at least three UBM pads can potentially produce several unwanted adverse effects. For example, large ribbon shaped electrical conduits can cause electrical interference problems within solid state integrated circuitry. In contrast, using serpentine shaped electrical conductors minimizes or at least reduces these types of interference problems while tightly folding or compressing the requisite length of the serpentine shaped conduit into the measurement zone. The area of serpentine shaped conductor is designed overlap at least three UBM pads at preferably over a 95% confidence. The snake-like shape of the serpentine shaped conductor provides the necessary length suitable for a Kelvin structure while minimizing electrical interference. Some preferred embodiments of the shapes of the serpentine shaped conductor include those having square wave shape, a triangular wave shape, a sawtooth wave shape, a sine wave shape and mixtures thereof.

When the serpentine shaped conductor (90) is electrically coupled to the at least three contact pads, then this electronic configuration can be used as a resistance measurement scheme. The resistance measurement scheme can be used to monitor the quality of the fabricated semiconductor wafer by monitoring metal quality, insulator quality and even degradation. Aluminum UBM pads have been monitored to assess the aluminum metal quality and/or corrosion.

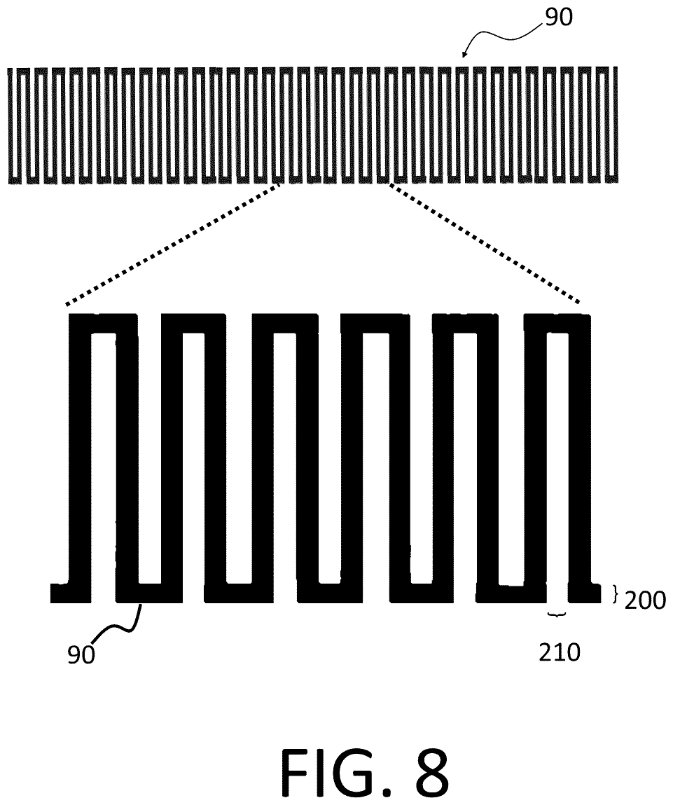

FIG. 8 shows a stylized top view of the serpentine shaped conductor (90) with a magnified portion showing even more detail. The width (200) of the serpentine shaped conductor can range from 5 μm to 100 μm. The separation gap (210) of the serpentine shaped conductor can range from 5 μm to 100 μm.

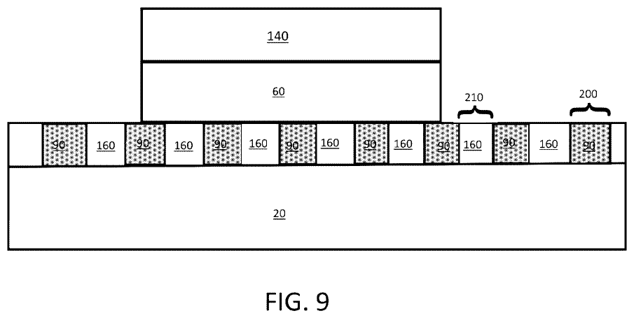

FIG. 9 depicts a stylized cross-sectional view of a UBM pad (60) electrically coupled to a serpentine shaped conductor (90). The UBM pad is shown to be electrically coupled to a bump (140) and to five of the eight cross section portions of the serpentine shaped conductor. Between the cross sectioned portions of the serpentine shaped conductor (90) are separation gaps filled with insulator layers (160). The insulator layers may be composed of any known electrically insulator material suitable for use in the semiconductor fabrication facilities and related industries. The width of the cross sectioned portions of the serpentine shaped conductor should be smaller than the size of the UBM pads and the size of the separation gap of the cross sectioned portions of the serpentine shaped conductor should be smaller than the size of the UBM pads. The insulator layers in the separation gaps and all eight of the cross sectioned portions of the serpentine shaped conductor are shown to be on a semiconductor substrate.

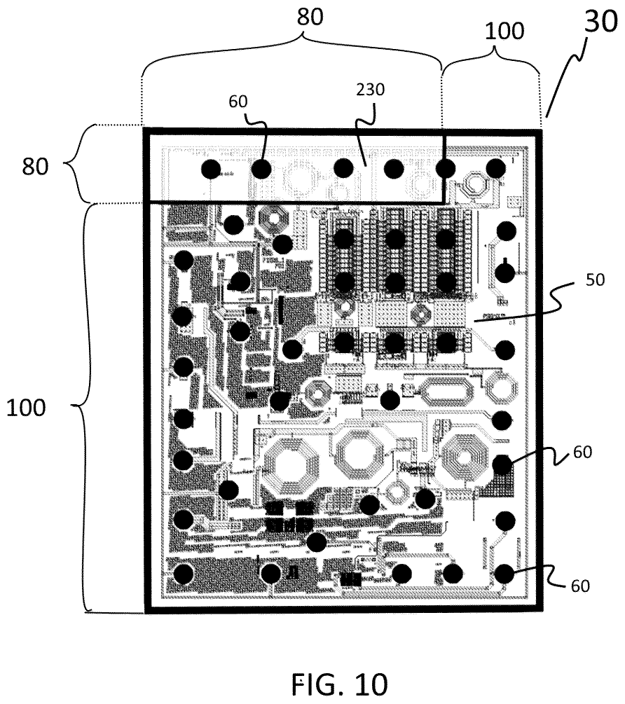

FIG. 10 depicts a stylized top view of a portion of a reticle imprint (30) that corresponds to a prime die (item (40) in FIG. 6) that is configured to be converted into a hybrid die (item (70) in FIG. 7). A plurality of UBM pads (60) are shown distributed all around on a prime integrated circuit (50). A lithography region (230) is shown overlapping an upper part of the reticle imprint corresponding to a prime die. This overlapped upper part of the reticle imprint of this prime die corresponds to the measurement zone (80) of the hybrid die (70) of FIG. 7. The non-overlapped part of the reticle imprint of this prime die corresponds to the reclaimed zone (100) of the hybrid die (70).

In particular, FIG. 10 shows that the lithographic region overlapping ½ of the UBM pads (60). The sizing of the lithographic region is designed to overlap at least three UBM pads of the reticle imprint of the prime die. This overlapped portion of the reticle imprint of the prime integrated circuit is then converted into the measurement zone of the hybrid die by subsequently forming the serpentine shaped conductor (90) onto this overlapped portion. The reclaimed zone (100) is fabricated by removing most of the circuitry structures not overlapped by the lithographic region (230) and by adding electrical structures and optionally adding at least one optical alignment structure. The measurement zone is fabricated by forming the serpentine shaped conductor on at least three UBM pads at the overlapped part of the reticle imprint so that the at least three under bump metallization pads of the measurement zone of the hybrid die are aligned to match positions of the at least three under metallization pads of the prime dies. The lithographic region (230) is designed to block an area of the reticle imprint of a prime die to preferably assure a 95% confident of overshadowing at least three UBM pads. The serpentine shaped conductor is then subsequently formed on at least three UBM pads onto the measurement zone of the hybrid die. This assures that lining up pins of test probes used in assessing both the prime die and in assessing hybrid dies can be properly aligned to set down on bumps (see elements (140) in FIG. 9) coupled to the at least three UBM pads of the measurement zone of the hybrid die. This identical positioning of the at least three UBM pads of both the prime die and the hybrid die minimizes misalignment damage to test probes set down on the bumps coupled to the at least three UBM pads of the measurement zone of the hybrid die.

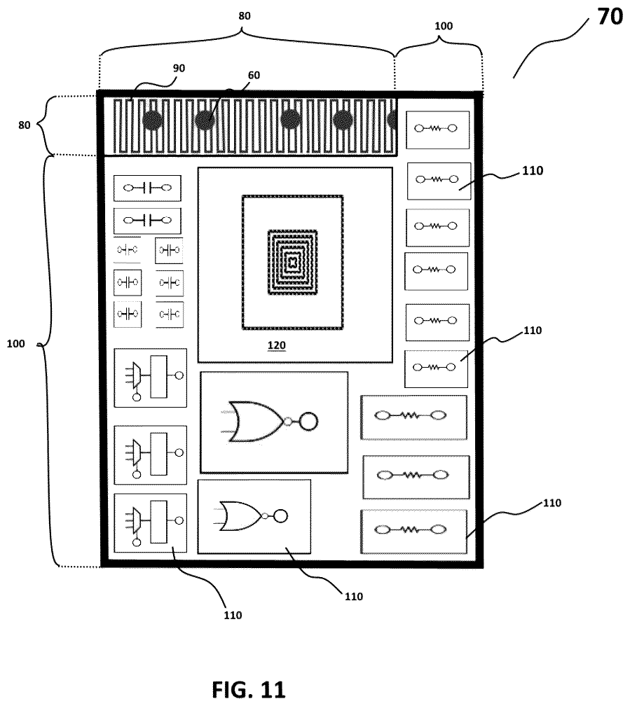

FIG. 11 depicts a hybrid die (70) formed from the arbitrarily selected reticle imprint (30) of the prime dies of FIG. 10. This assures that lining up pins of test probes used in assessing both the prime dies and hybrid dies can be properly aligned to minimize misalignment and damage to the pins of the test probes. This stylized depicted embodiment of the hybrid die comprises at least one optical alignment structure (120) and a plurality of electrical structures (110). The optical alignment structures (120) have been previously described and illustrated in FIGS. 2 and 5. The electrical test structures (110) have been previously described and illustrated in FIGS. 3, 5, and 7.

One preferred embodiment of a method of converting a prime die into a hybrid die comprises the protocols of selecting, providing, irradiating, stripping, adding, and forming. The selecting protocol includes an arbitrary selection of a first zone of the prime die on a semiconductor wafer that contains at the least three UBM pads. The providing protocol includes providing a lithographic cloak designed to overshadow the first zone. The irradiating protocol includes irradiating the prime die, using the lithographic cloak to overshadow the first zone, to expose a second zone of the prime die wherein the second zone is adjacent to the first zone. The stripping protocol includes stripping the second zone to remove circuitry structures to form a reclaimed zone of the hybrid die. The adding protocol includes adding electrical structures and at least one optical alignment structure onto the reclaimed zone. The forming protocol includes forming a serpentine shaped conductor on the at least three UBM pads of the first zone to form a measurement zone of the hybrid die.

The embodiments described above realize a number of advances or advantages in efficient wafer designs. By using the existing bump layout of that of a prime die, the amount of time during formation of the region is reduced. By replacing the perpendicular electrical lines (i.e., non-linear Kelvin structure) of the alignment die with the serpentine shaped conductor (i.e., a linear Kelvin structure) a space savings up to 92% can be used as the reclaimed zone of the hybrid die. By masking of a portion of the reticle of a prime die to eventually form the hybrid die provides the advantage of aligning the serpentine shaped electrode to overlap at least three UBM tabs. This minimizes or at least heavily reduces damage to probe pins uses to inspect the resultant dies of the wafer.

Circuits and devices in accordance with the present invention may be used alone or in combination with other components, circuits, and devices. Embodiments of the present invention may be fabricated as integrated circuits (ICs) or semiconductor chips, which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable various applications including signal, data, and power transmission; power management; wireless communications; data conversions; data processing; and other such applications.

A number of embodiments of the invention have been described. It is to be understood that various modifications may be made without departing from the spirit and scope of the invention.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below.

1. A semiconductor wafer comprising:
i) a plurality of prime dies, each prime die comprising:
a prime integrated circuit, and
a plurality of under bump metallization pads on the prime integrated circuit; and
ii) at least one hybrid die comprising:
a) a measurement zone comprising:
a serpentine shaped conductor; and
at least three under bump metallization pads coupled to the serpentine conductor wherein the at least three under bump metallization pads of the measurement zone of the hybrid die are aligned to match positions of at least three under bump metallization pads of the prime dies; and
b) a reclaimed zone comprising a first plurality of electrical test structures.

2. The semiconductor wafer of claim 1, wherein the reclaimed zone of the at least one hybrid die further comprises at least one optical alignment structure.

3. The semiconductor wafer of claim 1, further comprising knockout dies.

4. The semiconductor wafer of claim 3, wherein the knockout dies comprise a second plurality of electrical test structures.

5. The semiconductor of wafer of claim 4, wherein some of the knockout dies further comprise at least one optical alignment structure.

6. The semiconductor wafer of claim 5, wherein the at least one hybrid die and the knockout dies are positioned at center and four corners areas of a reticle imprint on the semiconductor wafer.

7. The semiconductor wafer of claim 1, further comprising bumps coupled to the at least three under bump metallization pads of the measurement zone of the at least one hybrid die.

8. The semiconductor wafer of claim 1, wherein the serpentine shaped conductor is sized to correspondingly overlap at least three under bump metallization pads of the plurality of under bump metallization pads that are on the prime integrated circuit of each prime die.

9. The semiconductor wafer of claim 1, wherein the reclaimed zone is at least 10 to 100 times larger than the measurement zone.

10. The semiconductor wafer of claim 1, wherein the serpentine shaped conductor has a shape selected from a square wave shape, a triangular wave shape, a sawtooth wave shape, a sine wave shape, a rectangular shape, or combinations thereof.

11. The semiconductor wafer of claim 1, wherein the serpentine shaped conductor is part of a Kelvin resistance measurement scheme for monitoring resistances.

12. The semiconductor wafer of claim 11, wherein the monitored resistances are used to ensure fabrication processing is within quality control limits.

13. The semiconductor wafer of claim 1, wherein the electrical test structures of the first plurality of electrical test structures are not identical to each other.

14. The semiconductor wafer of claim 4, wherein the electrical test structures of the second plurality of electrical test structures are not identical to each other.

15. The semiconductor wafer of claim 1, wherein the prime dies of the plurality of prime dies are not identical to each other.

16. The semiconductor wafer of claim 1, wherein the optical alignment structures of the at least one optical alignment structure of each of the knockout dies are not identical to each other.

17. A semiconductor wafer comprising:
i) a plurality of prime dies, each prime die comprising:
a prime integrated circuit, and
a plurality of under bump metallization pads on the prime integrated circuit; and
ii) at least one hybrid die comprising:
a) a measurement zone comprising:
a serpentine shaped conductor; and
under bump metallization pads coupled to the serpentine conductor; and
b) a reclaimed zone comprising:
a first plurality of electrical test structures; and
at least one optical alignment structure; and
c) a plurality of knockout dies comprising
a second plurality of electrical test structures, and
at least one optical alignment structure.

18. The semiconductor wafer of claim 17, wherein the at least one hybrid die and the knockout dies are positioned at center and four corners areas of a reticle imprint on the semiconductor wafer.

19. A prime die singulated from the semiconductor wafer of claim 1.

20. A method of converting a prime die into a hybrid die, the method comprising:
selecting a first zone of the prime die on a semiconductor wafer that contains at least three under bump metallization pads;
providing a lithographic region configured to overshadow the first zone;
irradiating the prime die, using the lithographic region to overshadow the first zone, to expose a second zone of the prime die wherein the second zone is adjacent to the first zone;
stripping the second zone to remove circuitry structures to form a reclaimed zone of the hybrid die;
adding electrical structures and at least one optical alignment structure onto the reclaimed zone; and
forming a serpentine shaped conductor on the at least three under bump metallization pads of the first zone to form a measurement zone of the hybrid die.
